(19) United States
(12) Patent Application Publication
(10) Pub. No.: US 2025/0296782 A1
(43) Pub. Date: Sep. 25, 2025

(54) ARTICLE CONVEYANCE SYSTEM AND ARTICLE CONVEYANCE METHOD

(71) Applicant: FUJI CORPORATION, Chiryu (JP)

(72) Inventors: Kentaro SEKI, Nagoya-shi (JP); Shigeto OYAMA, Kariya-shi (JP)

(73) Assignee: FUJI CORPORATION, Chiryu (JP)

(21) Appl. No.: 18/863,844

(22) PCT Filed: Jun. 14, 2022
(86) PCT No.: PCT/JP2022/023756

§ 371 Date: Nov. 7, 2024

(51) Int. Cl. B65G 35/06; B65G 43/02

(52) U.S. Cl. CPC B65G 35/06; B65G 43/02; B65G 2201/022; B65G 2203/0283

(57) ABSTRACT

An article conveyance system includes a station, a carriage, a detection section, and a control section. The station is configured to deliver an article. The carriage is configured to automatically convey the article into or out of the station and travel. The detection section is provided on at least one of the station and the carriage, and detects a relative position between the station and the carriage. When the detection section detects that the relative position is within a first range where the article can be delivered between the station and the carriage, the control section permits delivery of the article between the station and the carriage. When the detection section does not detect that the relative position is within the first range, the control section restricts the delivery of the article between the station and the carriage.

### TECHNICAL FIELD

The present description discloses a technique related to an article conveyance system and an article conveyance method.

### BACKGROUND ART

An article conveyance system described in Patent Literature 1 includes a station group, a first communication device, and a determination section. In the station group, multiple stations capable of delivering an article, which is used for a board work machine performing a predetermined board work on a board, are arranged side by side. The determination section determines whether a conveyance vehicle has arrived at a target station, which is the station where the conveyance vehicle is to send out or receive the article, by utilizing the first communication device.

An automated guided vehicle system described in Patent Literature 2 includes a marker magnetic tape on a floor surface, and performs conveyance by towing a towed vehicle by using an automated guided vehicle. The automated guided vehicle includes a front sensor capable of sensing the marker magnetic tape on a bottom surface of the automated guided vehicle.

### CITATION LIST

### Patent Literature

Patent Literature 1: WO 2021/144866

Patent Literature 2: JP-A-2020-044859

### BRIEF SUMMARY

### Technical Problem

However, in the article conveyance system described in Patent Literature 1 and the automated guided vehicle system described in Patent Literature 2, it is possible to determine that a carriage has arrived at the station where the carriage is to send out or receive the article, but depending on the positional relationship between the station and the carriage, there may be cases where a delivery of the article between the station and the carriage is difficult.

In view of such circumstances, the present description discloses an article conveyance system and an article conveyance method capable of reliably performing delivery of an article between a station and a carriage.

### Solution to Problem

The present description discloses an article conveyance system including a station, a carriage, a detection section, and a control section. The station is configured to deliver an article, which is used for a board work machine performing a predetermined board work on a board. The carriage is configured to automatically convey the article into or out of the station and travel. The detection section is provided on at least one of the station and the carriage, and is configured to detect a relative position between the station and the carriage. The control section is configured to permit delivery of the article between the station and the carriage when the detection section detects that the relative position is within a first range where the article is deliverable between the station and the carriage, and restrict the delivery of the article between the station and the carriage when the detection section does not detect that the relative position is within the first range.

The present description discloses an article conveyance method including a detection step and a control step. The detection step detects a relative position between a station configured to deliver an article, which is used for a board work machine performing a predetermined board work on a board, and a carriage configured to automatically convey the article into or out of the station and travel. The control step permits delivery of the article between the station and the carriage when the relative position detected in the detection step is within a first range where the article is deliverable between the station and the carriage, and restricts the delivery of the article between the station and the carriage when the relative position detected in the detection step is not within the first range.

### Advantageous Effects

With the article conveyance system, when the detection section detects that the relative position between the station and the carriage is within the first range, the control section permits delivery of the article between the station and the carriage. In addition, when the detection section does not detect that the relative position between the station and the carriage is within the first range, the control section restricts the delivery of the article between the station and the carriage. Therefore, the article conveyance system is capable of reliably performing the delivery of the article between the station and the carriage. The above description of the article conveyance system can be similarly applied to the article conveyance method.

### BRIEF DESCRIPTION OF DRAWINGS

FIG. 1 is a plan view illustrating a configuration example of a production facility.

FIG. 2 is a partial perspective view illustrating a configuration example of a station and a carriage.

FIG. 3 is a perspective view illustrating a state where an accommodation case capable of accommodating an article is mounted on the carriage in FIG. 2.

FIG. 4 is a block diagram illustrating an example of a control block of an article conveyance system.

FIG. 5 is a flowchart illustrating an example of a control procedure according to the article conveyance system.

FIG. 6 is a diagram illustrating an example of determination and control according to control timing.

FIG. 7 is a partial perspective view illustrating an example of a state of a detector when a station side contact portion and a carriage side contact portion are not in contact with each other.

FIG. 8 is a partial perspective view illustrating an example of a state of the detector when the station side contact portion and the carriage side contact portion are in contact with each other.

FIG. 9 is a schematic view illustrating an example of a positional relationship between the station and the carriage.

FIG. 10 is a perspective view illustrating another configuration example of the carriage.

### DESCRIPTION OF EMBODIMENTS

### 1. Embodiments

### 1-1. Configuration Example of Production Facility 1

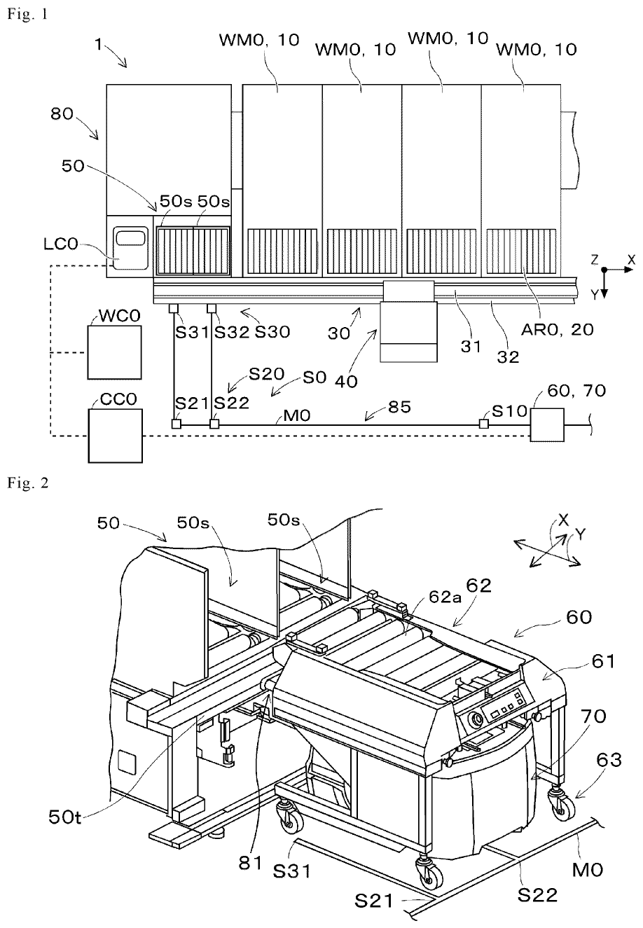

Article conveyance system 80 can be applied to various production facilities 1 that produce board products. As illustrated in FIG. 1, production facility 1 of the embodiment includes at least one component mounter 10 (four in FIG. 1), exchange system 30, article movement device 40, station group 50, carriage 60, automated guided vehicle 70, line control device LC0, production management device WC0, and conveyance management device CC0. In the following description, a horizontal width direction of component mounter 10 and a conveyance direction of the board are defined as the X direction. In addition, a horizontal depth direction of component mounter 10 and a direction perpendicular to the X direction in the horizontal plane are defined as the Y direction. Furthermore, a vertical direction perpendicular to the X direction and the Y direction is defined as the Z direction.

At least one (or four) component mounter(s) 10 is installed along the conveyance direction of the board (X direction). Component mounter 10 is included in board work machine WM0 performing a predetermined board work on the board. Component mounter 10 mounts multiple components on a board, which is conveyed into and positioned at a predetermined position, and conveys out the board on which the components are mounted. That is, the board work by component mounter 10 includes conveying-in work, positioning work, and conveying-out work of the board. Further, the board work by component mounter 10 includes component supply work, collect work, and mounting work.

For example, component mounter 10 includes a component supply device that supplies components to be mounted on the board. Multiple feeders 20 are provided in the component supply device in an attachable and detachable manner. Feeder 20 is included in article AR0 used for the component supply work by component mounter 10. Further, the component supply device includes at least one slot capable of installing multiple feeders 20. The component supply device of the embodiment is provided at two positions of a first position and a second position.

The first position operably holds installed feeder 20. The operation of feeder 20 installed in the first position is controlled in the board work by component mounter 10, and the components are sequentially supplied by a pick-up section provided at a predetermined position of feeder 20. The second position is disposed below the first position to stock installed feeder 20. That is, the second position preliminarily holds feeder 20 used for production and temporarily holds feeder 20 that has been used for production.

The exchange work of feeder 20 between the first position and the second position, and replenishment work and recovery work of feeder 20 are performed using exchange system 30 and article movement device 40. Specifically, as illustrated in FIG. 1, exchange system 30 includes first rail 31 and second rail 32. First rail 31 and second rail 32 form a traveling path of article movement device 40. First rail 31 and second rail 32 are provided along a disposition direction of at least one (or four) component mounter(s) 10 (the conveyance direction (X direction) of the board). First rail 31 and second rail 32 extend over substantially the entire area of the conveyance direction (X direction) of the board in production facility 1.

Article movement device 40 is provided so as to be able to travel along the traveling path formed by first rail 31 and second rail 32. Article movement device 40 receives the electric power supplied from a power transmission section by contactless power supply, for example, via a power receiving section provided to face the power transmission section provided in first rail 31. The electric power received by the power receiving section is used for traveling of article movement device 40, a predetermined work, or the like via a power receiving circuit. It should be noted that article movement device 40 detects, for example, a position (current position) on the traveling path by a position detection device. The position detection device can detect the position (current position) of article movement device 40 on the traveling path, for example, by optical position detection, position detection using electromagnetic induction, or the like.

Further, the predetermined work described above includes exchange work for exchanging a device provided in board work machine WM0 in an attachable and detachable manner, such as component mounter 10, with board work machine WM0. In the embodiment, article movement device 40 uses feeder 20 that supplies the components to be mounted on the board as a device and performs the exchange work of feeder 20 with component mounter 10, which is board work machine WM0. Further, article movement device 40 can perform the exchange work of feeder 20 with station group 50.

Specifically, article movement device 40 performs the exchange work of feeder 20 between the first position and the second position of the component supply device of component mounter 10. Further, article movement device 40 conveys feeder 20 from station group 50 to the first position or the second position of the component supply device and performs the replenishment work of feeder 20. Further, article movement device 40 conveys feeder 20, which is made unnecessary in component mounter 10, from the component supply device to station group 50 and performs the recovery work of feeder 20.

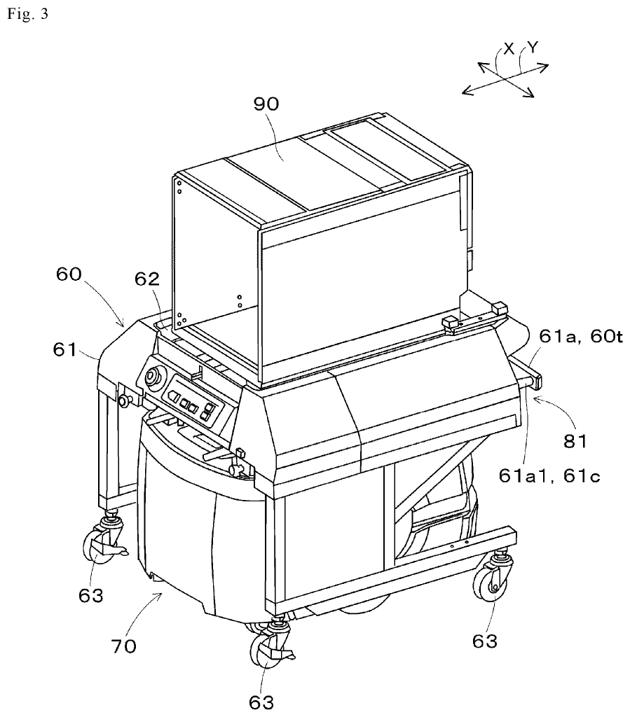

Station group 50 is provided on a board convey-in side (on the left side in the drawing of FIG. 1) of production facility 1. As illustrated in FIGS. 1 and 2, station group 50 is provided with at least one station 50s (two in FIGS. 1 and 2) configured to deliver article AR0 used for board work machine WM0, such as feeder 20. Station 50s need only be capable of delivering article AR0, and may take various forms. For example, station 50s includes multiple rollers, and can convey article AR0 in from carriage 60 and convey article AR0 out to carriage 60.

Station 50s can also accommodate accommodation case 90 illustrated in FIG. 3 capable of accommodating article AR0. In this case as well, station 50s can convey accommodation case 90 in from carriage 60 and convey accommodation case 90 out to carriage 60 by multiple rollers. Accommodation case 90 includes, for example, multiple slots, and feeder 20 can be provided in each slot. Feeder 20, which is installed in the slot of accommodation case 90 conveyed in station 50s, is supplied with electric power from station 50s, via accommodation case 90 and then becomes in a state capable of communicating with line control device LC0. As a result, identification information of the slot of accommodation case 90 and feeder 20, which is installed in the slot, are associated with each other and recorded in line control device LC0.

Carriage 60 is configured to automatically convey article AR0 into or out of station 50s and travel. Carriage 60 need only be capable of automatically performing the operations described above, and may take various forms. For example, as illustrated in FIGS. 2 and 3, carriage 60 includes carriage main body section 61, loading platform 62, and multiple (for example, four) wheels 63. Loading platform 62 is provided at the upper portion of carriage main body section 61, and can be mounted with article AR0. As illustrated in FIG. 3, loading platform 62 may be equipped with accommodation case 90 capable of accommodating article AR0.

Loading platform 62 includes multiple rollers 62a, and can convey article AR0 in to station 50s and convey article AR0 out from station 50s. Further, loading platform 62 can convey accommodation case 90 in to station 50s and convey accommodation case 90 out from station 50s. Loading platform 62 fixes article AR0 or accommodation case 90 except when article AR0 or accommodation case 90 is being conveyed into or out of station 50s. Loading platform 62 releases the fixation of article AR0 or accommodation case 90 when article AR0 or accommodation case 90 is being conveyed into or out of station 50s.

Multiple (four) wheels 63 are provided at the lower portion of carriage main body section 61, and carriage 60 can travel. Carriage 60 of the embodiment is towed and travels by automated guided vehicle 70. Specifically, in a state where automated guided vehicle 70 is disposed at the lower portion of carriage main body section 61, automated guided vehicle 70 is connected to carriage main body section 61 to be able to tow carriage 60. Automated guided vehicle 70 need only be capable of automatically traveling, and various known automated guided vehicles can be used.

Line control device LC0 is capable of inputting and outputting to and from each device constituting production facility 1 and various data via a network. Line control device LC0 monitors the operational status of production facility 1 and integrally controls board work machine WM0 such as component mounter 10, exchange system 30, article movement device 40, and station group 50. Line control device LC0 stores various data for controlling board work machine WM0, exchange system 30, article movement device 40, and station group 50.

Production management device WC0 can manage at least one (in FIG. 1, one) production facility 1. Production management device WC0 is provided to be able to communicate with line control device LC0 of at least one (one) production facility 1, and can manage the production of board products by at least one (one) production facility 1. Conveyance management device CC0 can manage carriage 60 and automated guided vehicle 70. Conveyance management device CC0 is provided to be able to communicate with carriage 60, automated guided vehicle 70, line control device LC0, and production management device WC0, and based on the production status of the board products in production facility 1, conveyance management device CC0 causes carriage 60 and automated guided vehicle 70 to travel and causes carriage 60 to perform the delivery of article AR0.

As illustrated in FIG. 1, production facility 1 is provided with guide portion 85. Guide portion 85 is a member provided along the travel route of carriage 60 and guides travel of carriage 60. Carriage 60 travels while recognizing guide portion 85. Guide portion 85 need only be capable of guiding the travel of carriage 60, and may take various forms. For example, guide portion 85 includes guide member M0 indicating traveling path of carriage 60 and indicator member S0 serving as an indicator when carriage 60 travels. Guide member M0 and indicator member S0 improve the traveling accuracy of carriage 60.

Guide member M0 and indicator member S0 may take various forms. In the embodiment, guide member M0 and indicator member S0 are formed of magnetic tape. Further, carriage 60 of the embodiment is towed by automated guided vehicle 70. Automated guided vehicle 70 towing carriage 60 can prevent automated guided vehicle 70 (carriage 60) from departing from the traveling path to be traveled by making automated guided vehicle 70 travel while sensing guide member M0. Automated guided vehicle 70 can recognize the traveling position of automated guided vehicle 70 (carriage 60) by sensing indicator member S0.

For example, indicator member S0 includes a reference member indicating reference position S10, a via member indicating via position S20, and a target member indicating target position S30. In addition, since station group 50 of the embodiment includes two stations 50s, the via member includes first via member indicating first via position S21 and second via member indicating second via position S22. The target member includes a first target member indicating first target position S31 and a second target member indicating second target position S32. For example, automated guided vehicle 70 towing carriage 60 recognizes that automated guided vehicle 70 (carriage 60) is traveling at first via position S21 by sensing the first via member. For example, when automated guided vehicle 70 (carriage 60) and conveyance management device CC0 communicate with each other and conveyance management device CC0 can recognize the traveling position of automated guided vehicle 70 (carriage 60), indicator member S0 may be omitted.

Automated guided vehicle 70 towing carriage 60 travels toward target station 50s along a travel route that is programmed in advance or a travel route instructed by conveyance management device CC0. For example, consider the case where station 50s on the left side of the drawing illustrated in FIG. 1 is target station 50s, and automated guided vehicle 70 towing carriage 60 moves from reference position S10 to first target position S31. In this case, when automated guided vehicle 70 towing carriage 60 senses the first via member, automated guided vehicle 70 rotates 90 degrees to the right and advances straight. Then, automated guided vehicle 70 towing carriage 60 stops when the first target member is sensed.

The same applies when station 50s on the right side of the drawing illustrated in FIG. 1 is target station 50s, and automated guided vehicle 70 towing carriage 60 is moved from reference position S10 to second target position S32. In this case, when automated guided vehicle 70 towing carriage 60 senses the second via member, automated guided vehicle 70 rotates 90 degrees to the right and advances straight. Then, automated guided vehicle 70 towing carriage 60 stops when the second target member is sensed. Automated guided vehicle 70 towing carriage 60 can sense station 50s when the distance between automated guided vehicle 70 and station 50s becomes equal to or shorter than a predetermined distance, and can stop even when the first target member or the second target member is not sensed.

When arriving at target station 50s, carriage 60 sends article AR0 or accommodation case 90 out to station 50s, and station 50s receives article AR0 or accommodation case 90 from carriage 60. Further, station 50s can send article AR0 or accommodation case 90 out to carriage 60, and carriage 60 can receive article AR0 or accommodation case 90 from station 50s.

Further, carriage 60 can also send article AR0 or accommodation case 90 out to first station 50s, move to second station 50s, and receive article AR0 or accommodation case 90 from station 50s. Further, carriage 60 can receive article AR0 or accommodation case 90 from first station 50s, move to second station 50s, and send article AR0 or accommodation case 90 received from first station 50s out to second station 50s. In the following description, the delivery of article AR0 is described. Article AR0 need not be accommodated in accommodation case 90, and may be accommodated in accommodation case 90.

### 1-2. Configuration Example of Article Conveyance System 80

Depending on the positional relationship between station 50s and carriage 60, there may be cases where it is difficult to deliver article AR0 between station 50s and carriage 60. For example, the cases can occur when, at the position where carriage 60 has stopped after detecting the target member, the relative position between station 50s and carriage 60 is spaced to such a degree that it is difficult to deliver article AR0, or the relative angle between station 50s and carriage 60 is tilted to such a degree that it is difficult to deliver article AR0. In such cases, there is a possibility that article AR0 may fall during the delivery of article AR0. In the embodiment, article conveyance system 80 is provided.

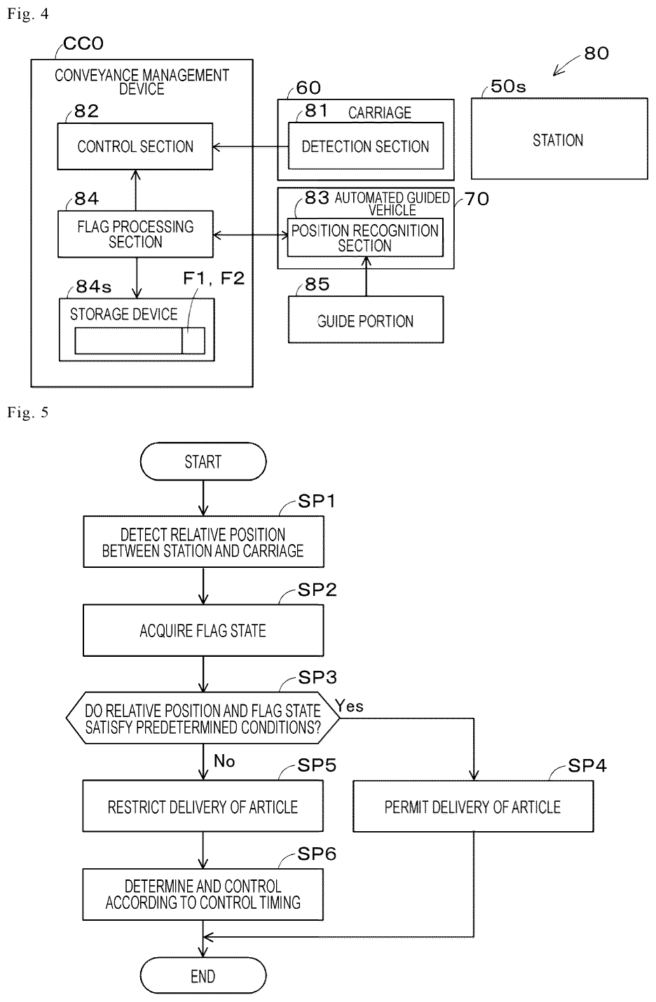

Article conveyance system 80 includes station 50s, carriage 60, detection section 81, and control section 82. Article conveyance system 80 may include position recognition section 83. Article conveyance system 80 may include flag processing section 84. Article conveyance system 80 may include guide portion 85. As illustrated in FIG. 4, article conveyance system 80 of the embodiment includes station 50s, carriage 60, detection section 81, control section 82, position recognition section 83, flag processing section 84, and guide portion 85. Further, carriage 60 of the embodiment is towed by automated guided vehicle 70.

Detection section 81, control section 82, position recognition section 83, and flag processing section 84 can be provided in various detectors, storage devices, arithmetic devices, control devices, management devices, and the like. For example, at least one of detection section 81, control section 82, position recognition section 83, and flag processing section 84 may be provided in station 50s, carriage 60, automated guided vehicle 70, or the like. At least one of control section 82, position recognition section 83, and flag processing section 84 may be provided in line control device LC0, production management device WC0, conveyance management device CC0, or the like.

At least one of control section 82, position recognition section 83, and flag processing section 84 may be formed on a cloud. As illustrated in FIG. 4, in article conveyance system 80 of the embodiment, detection section 81 is provided on carriage 60. Control section 82 and flag processing section 84 are provided in conveyance management device CC0. Position recognition section 83 is provided in automated guided vehicle 70 towing carriage 60. Guide portion 85 is provided on a floor surface of production facility 1.

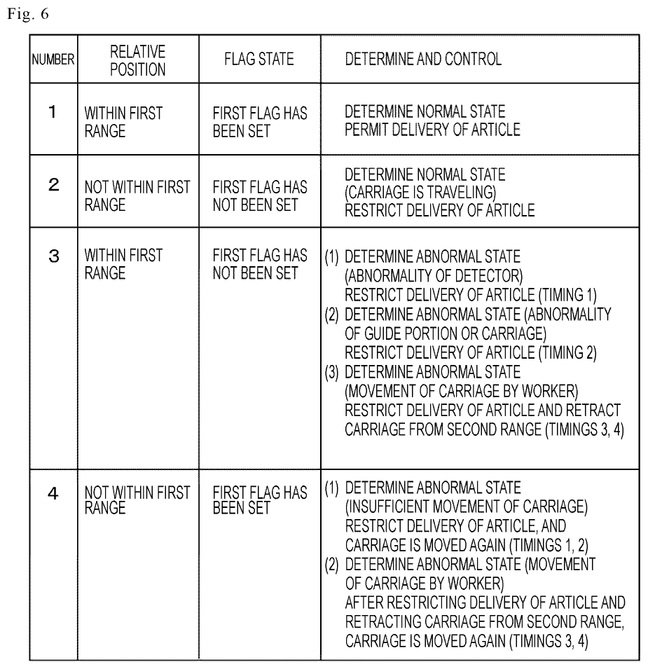

Article conveyance system 80 of the embodiment performs control according to the flowchart illustrated in FIG. 5. Detection section 81 performs the processing illustrated in step SP1. Control section 82 performs processing and determination illustrated in step SP2 to step SP6. FIG. 6 illustrates an example of the determination and control illustrated in step SP6.

### 1-2-1. Detection Section 81

Detection section 81 is provided on at least one of station 50s and carriage 60, and detects relative position 81p between station 50s and carriage 60 (step SP1 illustrated in FIG. 5). Detection section 81 need only be capable of detecting relative position 81p, and may take various forms. For example, detection section 81 can detect relative position 81p between station 50s and carriage 60 (relative position 81p of carriage 60 with respect to station 50s or relative position 81p of station 50s with respect to carriage 60, hereinafter the same) using a range sensor such as a laser displacement meter. Detection section 81 can also detect the relative angle between station 50s and carriage 60 (the relative angle of carriage 60 with respect to station 50s or the relative angle of station 50s with respect to carriage 60, hereinafter the same) using a range sensor such as a laser displacement meter.

Detection section 81 can also detect relative position 81p between station side contact portion 50t provided on station 50s and carriage side contact portion 60t provided on carriage 60. Detection section 81 can also detect the relative angle between station side contact portion 50t and carriage side contact portion 60t. Detection section 81 can also detect whether station side contact portion 50t and carriage side contact portion 60t are in contact with each other. As illustrated in FIGS. 2 and 3, detection section 81 of the embodiment is provided on carriage main body section 61 on the advancing direction side of carriage 60. Detection section 81 may also be provided on station 50s. Detection section 81 may be provided on both station 50s and carriage 60.

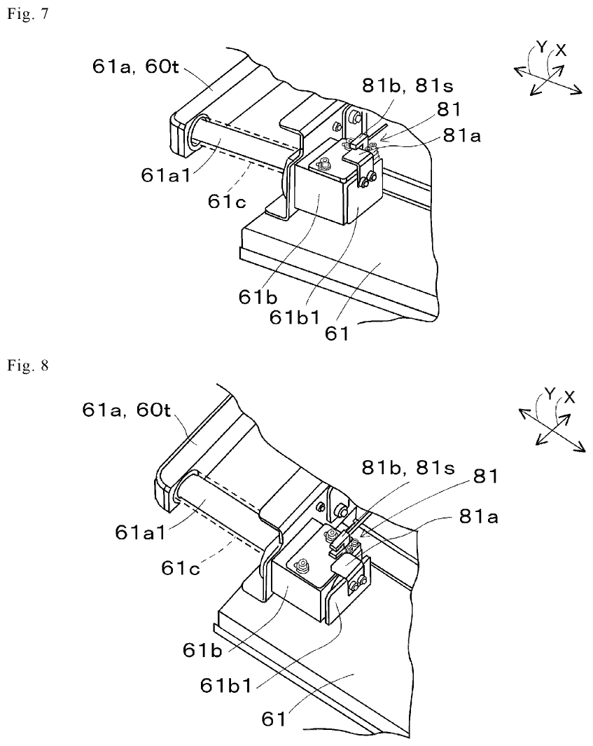

As illustrated in FIGS. 7 and 8, carriage main body section 61 includes bumper portion 61a, pair of support portions 61b and 61b, and pair of elastic members 61c and 61c. Bumper portion 61a corresponds to carriage side contact portion 60t. Bumper portion 61a is provided along the width direction of carriage 60 on carriage main body section 61 on the advancing direction side of carriage 60. Bumper portion 61a is formed of, for example, metal, hard resin, or the like, to withstand a predetermined number of times of contact with station side contact portion 50t. Bumper portion 61a need only be capable of coming into contact with station side contact portion 50t provided along the width direction of station 50s, and may take various shapes. For example, bumper portion 61a of the embodiment is formed in a plate-like rod shape.

Bumper portion 61a can come into contact with station side contact portion 50t at least two points spaced apart by a predetermined distance in the width direction of carriage 60. Specifically, bumper portion 61a includes pair of support rods 61a1 and 61a1 at positions spaced apart by a predetermined distance in the width direction of carriage 60. Similar to bumper portion 61a, pair of support rods 61a1 and 61a1 are formed in a cylindrical columnar rod shape using, for example, metal, hard resin, or the like.

Each of pair of support portions 61b and 61b includes a support hole penetrating in the advancing direction and the retreating direction of carriage 60. The support hole supports support rod 61a1 to be movable in the advancing direction and the retreating direction of carriage 60. That is, pair of support portions 61b and 61b support bumper portion 61a to be movable in parallel along the advancing direction and the retreating direction of carriage 60 with respect to carriage main body section 61. Each of pair of support portions 61b and 61b includes contact plate 61b1 on the retreating direction side of carriage 60. Contact plate 61b1 is formed larger than the outer diameter of the support hole, and prevents support rod 61a1 from slipping out of support portion 61b in the advancing direction of carriage 60.

Pair of elastic members 61c and 61c are provided between bumper portion 61a and pair of support portions 61b and 61b. Specifically, each of pair of elastic members 61c and 61c surrounds the outer peripheral surface of support rod 61a1. As pair of elastic members 61c and 61c, for example, a cylindrical coil spring can be used. Pair of elastic members 61c and 61c can expand and contract in the advancing direction and the retreating direction of carriage 60 and are assembled in a compressed state.

That is, pair of elastic members 61c and 61c bias bumper portion 61a toward the advancing direction side of carriage 60 with respect to carriage main body section 61. Thus, when bumper portion 61a and station side contact portion 50t are not in contact with each other, contact plate 61b1 is maintained in contact with support portion 61b. When bumper portion 61a comes into contact with station side contact portion 50t, pair of elastic members 61c and 61c are further compressed to absorb the impact when bumper portion 61a and station side contact portion 50t come into contact with each other.

Detection section 81 detects whether bumper portion 61a corresponding to carriage side contact portion 60t, and station side contact portion 50t are in contact with each other. Detection section 81 of the embodiment includes sensor dog 81a and light shielding detection sensor 81b. As illustrated in FIGS. 7 and 8, sensor dog 81a is formed from a plate member in an L-shaped and is attached to contact plate 61b1. Light shielding detection sensor 81b is provided above support portion 61b in the vertical direction. Light shielding detection sensor 81b includes a light emitting section and a light receiving section that are spaced apart from each other in the vertical direction, and detects whether the detection light emitted from the light emitting section to the light receiving section is in a light shielding state in which the light is shielded by sensor dog 81a.

As illustrated in FIG. 7, when bumper portion 61a corresponding to carriage side contact portion 60t, and station side contact portion 50t are not in contact with each other, contact plate 61b1 is in contact with support portion 61b. In this case, sensor dog 81a is inserted between the light emitting section and the light receiving section of light shielding detection sensor 81b, and light shielding detection sensor 81b detects the light shielding state. Thus, detection section 81 can recognize that bumper portion 61a corresponding to carriage side contact portion 60t, and station side contact portion 50t are not in contact with each other (are spaced apart from each other).

When bumper portion 61a corresponding to carriage side contact portion 60t, and station side contact portion 50t is in contact with each other, and carriage 60 further moves toward station 50s, elastic member 61c is compressed. Accordingly, as illustrated in FIG. 8, bumper portion 61a, support rod 61a1, contact plate 61b1, and sensor dog 81a undergo relative movement to the retreating direction side of carriage 60 with respect to carriage main body section 61. At this time, contact plate 61b1 is spaced apart from support portion 61b. In this case, sensor dog 81a is spaced apart from between the light emitting section and the light receiving section of light shielding detection sensor 81b, and light shielding detection sensor 81b detects that the detection light is not in the light shielding state (light receiving state). Thus, detection section 81 can recognize that bumper portion 61a corresponding to carriage side contact portion 60t, and station side contact portion 50t are in contact with each other

Detection section 81 of the embodiment detects the contact between carriage 60 and station 50s by light shielding detection sensor 81b. Detection section 81 can detect the contact using other sensors. For example, detection section 81 may include a proximity sensor in support portion 61b. The proximity sensor can detect the contact by the relative movement of support rod 61a1 in the retreating direction of carriage 60. Detection section 81 of the embodiment detects a relative position in the Y direction between bumper portion 61a corresponding to carriage side contact portion 60t, and station side contact portion 50t. Detection section 81 can also detect a relative position in the X direction between bumper portion 61a corresponding to carriage side contact portion 60t, and station side contact portion 50t.

Further, in detection section 81 of the embodiment, light shielding detection sensor 81b that detects the contact between carriage 60 and station 50s is provided at positions (two positions spaced apart from each other by a predetermined distance in the X direction) spaced apart by a predetermined distance in the width direction of carriage 60. Thus, Detection section 81 can detect the relative angle between carriage 60 and station 50s. In addition, automated guided vehicle 70 (carriage 60) can adjust the travel such that the relative angle becomes zero (such that carriage side contact portion 60t and station side contact portion 50t are parallel to each other).

### 1-2-2. Control Section 82

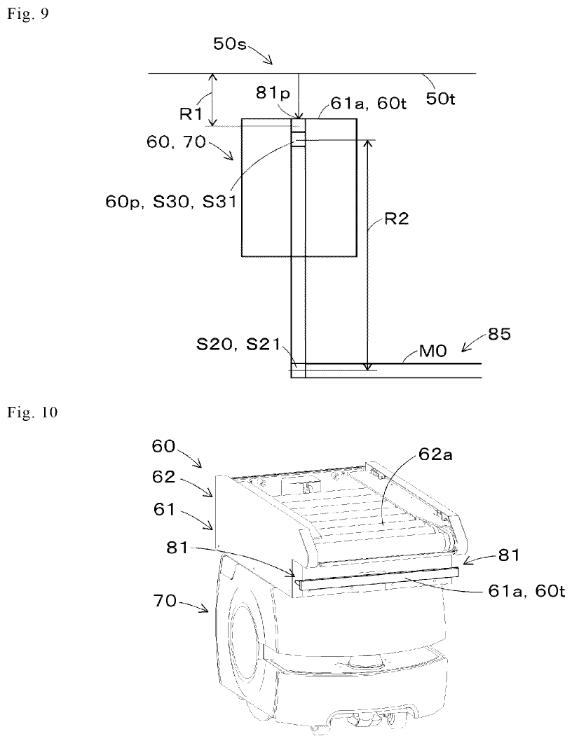

As illustrated in FIG. 9, for example, as relative position 81p of carriage 60 with respect to station 50s is spaced apart from station 50s, the gap between station 50s and carriage 60 increases. As the gap increases, the possibility of article AR0 falling during the delivery of article AR0 between station 50s and carriage 60 increases.

When detection section 81 detects that relative position 81p is within first range R1 where article AR0 is deliverable between station 50s and carriage 60, control section 82 permits the delivery of article AR0 between station 50s and carriage 60. When detection section 81 does not detect that relative position 81p is within first range R1, control section 82 restricts the delivery of article AR0 between station 50s and carriage 60.

First range R1 need only be a range where article AR0 is deliverable between station 50s and carriage 60, and may be set optionally. First range R1 can also be set in accordance with, for example, the type of article AR0 (the size, the weight, and the like of article AR0) and the state of article AR0 when the delivery is performed (whether article AR0 is accommodated in accommodation case 90). In either case, first range R1 can be acquired in advance by, for example, a simulation, verification by an actual machine, or the like.

When station side contact portion 50t provided in station 50s and carriage side contact portion 60t provided in carriage 60 are in contact with each other, no gap is generated between station 50s and carriage 60. In this case, during the delivery of article AR0 between station 50s and carriage 60, the fall of article AR0 due to the gap can be prevented.

When station side contact portion 50t provided in station 50s and carriage side contact portion 60t provided in carriage 60 are in contact with each other, detection section 81 may detect that relative position 81p is within first range R1. When station side contact portion 50t and carriage side contact portion 60t are not in contact with each other, it is preferable that detection section 81 does not detect that relative position 81p is within first range R1.

In the embodiment described above, when station side contact portion 50t and carriage side contact portion 60t are in contact with each other, control section 82 permits the delivery of article AR0 between station 50s and carriage 60. When station side contact portion 50t and carriage side contact portion 60t are not in contact with each other (are spaced apart from each other), control section 82 restricts the delivery of article AR0 between station 50s and carriage 60. Moreover, the above description of station 50s, carriage 60, detection section 81, and control section 82 described above can also be appropriately applied to the embodiments described below.

### 1-2-3. Position Recognition Section 83, Flag Processing Section 84, and Guide Portion 85

In the embodiment described above, control section 82 determines whether to permit the delivery of article AR0 between station 50s and carriage 60 based on the detection result detected by detection section 81. However, for example, there is a possibility that a failure may occur in production facility 1, for example, an abnormality may occur in detector 81s of detection section 81 (corresponding to light shielding detection sensor 81b described above).

Article conveyance system 80 of the embodiment includes position recognition section 83, flag processing section 84, and guide portion 85. Position recognition section 83 recognizes traveling position 60p where carriage 60 is traveling. As described above, guide portion 85 is a member provided along the travel route of carriage 60 and guide the travel of carriage 60. Carriage 60 (in the embodiment, automated guided vehicle 70 towing carriage 60) travels while recognizing guide portion 85.

Specifically, guide portion 85 includes guide member M0 indicating traveling path of carriage 60 and indicator member S0 serving as an indicator when carriage 60 travels. Automated guided vehicle 70 towing carriage 60 can prevent automated guided vehicle 70 (carriage 60) from departing from the traveling path to be traveled by making automated guided vehicle 70 travel while sensing guide member M0. Automated guided vehicle 70 can recognize the traveling position of automated guided vehicle 70 (carriage 60) by sensing indicator member S0.

Flag processing section 84 sets first flag F1 at a timing at which traveling position 60p of carriage 60 recognized by position recognition section 83 reaches target position S30 at which carriage 60 performs the delivery of article AR0 to and from station 50s, or at a timing at which traveling position 60p of carriage 60 enters second range R2 in which the adjustment operation to target position S30 is performed. In addition, flag processing section 84 unsets first flag F1 at a timing at which traveling position 60p of carriage 60 recognized by position recognition section 83 is away from target position S30, or at a timing at which traveling position 60p of carriage 60 is retracted outside second range R2.

That is, flag processing section 84 can set first flag F1 at a timing at which traveling position 60p of carriage 60 recognized by position recognition section 83 reaches target position S30, and unset first flag F1 at a timing at which traveling position 60p of carriage 60 recognized by position recognition section 83 is away from target position S30. Flag processing section 84 can set first flag F1 at a timing at which traveling position 60p of carriage 60 recognized by position recognition section 83 enters second range R2, and unset first flag F1 at a timing at which traveling position 60p of carriage 60 recognized by position recognition section 83 is retracted outside second range R2.

Further, flag processing section 84 can set first flag F1 at a timing at which traveling position 60p of carriage 60 recognized by position recognition section 83 reaches target position S30, and unset first flag F1 at a timing at which traveling position 60p of carriage 60 recognized by position recognition section 83 is retracted outside second range R2. Flag processing section 84 can set first flag F1 at a timing at which traveling position 60p of carriage 60 recognized by position recognition section 83 enters second range R2, and unset first flag F1 at a timing at which traveling position 60p of carriage 60 recognized by position recognition section 83 is away from target position S30.

Flag processing section 84 of the embodiment operates while carriage 60 is automatically operating. The adjustment operation includes an operation of bringing carriage 60 closer to target position S30 while adjusting the position and the angle of carriage 60 with respect to station 50s in a movement to target position S30 where carriage 60 performs the delivery of article AR0 to and from station 50s. For example, consider the case where station 50s on the left side of the drawing illustrated in FIG. 1 is target station 50s, and automated guided vehicle 70 towing carriage 60 moves from reference position S10 to first target position S31.

In this case, when automated guided vehicle 70 towing carriage 60 senses the first via member indicating first via position S21, automated guided vehicle 70 rotates 90 degrees to the right and advances straight. The adjustment operation is performed while automated guided vehicle 70 towing carriage 60 is traveling from first via position S21 to first target position S31. Specifically, automated guided vehicle 70 towing carriage 60 brings carriage 60 closer to target position S30 while adjusting the position and the angle of carriage 60 so that station side contact portion 50t and carriage side contact portion 60t are brought closer to each other in a parallel state. In this case, second range R2 is a range from first via position S21 to first target position S31. Similarly, the adjustment operation is performed while automated guided vehicle 70 towing carriage 60 is traveling from second via position S22 to second target position S32. In this case, second range R2 is a range from second via position S22 to second target position S32.

In this way, when traveling position 60p of carriage 60 recognized by position recognition section 83 enters second range R2, there is a possibility that station 50s and carriage 60 may be brought closer to each other. When traveling position 60p of carriage 60 recognized by position recognition section 83 reaches target position S30, station 50s and carriage 60 are already brought closer to each other. Flag processing section 84 sets first flag F1 at these timings. Conversely, flag processing section 84 unsets first flag F1 at a timing at which traveling position 60p of carriage 60 recognized by position recognition section 83 is away from target position S30, or at a timing at which traveling position 60p of carriage 60 is retracted outside second range R2. Accordingly, control section 82 can recognize a state where station 50s and carriage 60 are already brought closer to each other, or a possibility that station 50s and carriage 60 may be brought closer to each other.

Second range R2 can be optionally set. For example, second range R2 can be set in a range (a range of a predetermined distance from station 50s) in which there is a possibility of interference with other members, including station 50s, when carriage 60 revolves. In addition, flag processing section 84 can unset first flag F1 not only at a timing at which carriage 60 arrives at target station 50s, delivers article AR0, and then is spaced apart from target station 50s by a predetermined distance, but also at various timings. For example, flag processing section 84 can unset first flag F1 at a timing at which automated guided vehicle 70 towing carriage 60 starts moving from reference position S10. Further, flag processing section 84 can unset first flag F1 at a timing at which carriage 60, after an abnormality occurs in carriage 60, returns to a normal state and is spaced apart from station 50s by a predetermined distance. Flag processing section 84 can resume the control of carriage 60 after the control of carriage 60 is stopped, and can unset first flag F1 at a timing at which carriage 60 is spaced apart from station 50s by a predetermined distance.

First flag F1 can be provided in memory areas of various storage devices. For example, as illustrated in FIG. 4, first flag F1 is provided in a predetermined memory area of storage device 84s of conveyance management device CC0. When first flag F1 is set by flag processing section 84, high level information (for example, 1) is stored in the memory area. When first flag F1 is unset by flag processing section 84, low level information (for example, 0) is stored in the memory area. The above description of the storage device can be similarly applied to second flag F2 described later.

In the embodiment in which article conveyance system 80 includes position recognition section 83 and flag processing section 84, control section 82 can perform the determination and the control illustrated in FIG. 6 (step SP2 to step SP6 illustrated in FIG. 5). Article conveyance system 80 of the embodiment may adopt a configuration in which the following determinations and controls are optionally combined. For example, when detection section 81 detects that relative position 81p is within first range R1 and flag processing section 84 has set first flag F1, the detection result detected by detection section 81 does not contradict the state of first flag F1 processed by flag processing section 84. Similarly, when detection section 81 does not detect that relative position 81p is within first range R1 and flag processing section 84 has not set first flag F1, the detection result detected by detection section 81 does not contradict the state of first flag F1 processed by flag processing section 84. Accordingly, control section 82 determines that the processing performed by detection section 81 and flag processing section 84 is in a normal state.

In contrast, when detection section 81 detects that relative position 81p is within first range R1 and flag processing section 84 has not set first flag F1, the detection result detected by detection section 81 contradicts the state of first flag F1 processed by flag processing section 84. Similarly, when detection section 81 does not detect that relative position 81p is within first range R1 and flag processing section 84 has set first flag F1, the detection result detected by detection section 81 contradicts the state of first flag F1 processed by flag processing section 84. Accordingly, control section 82 determines that the processing performed by detection section 81 and flag processing section 84 is in an abnormal state.

When detection section 81 detects that relative position 81p is within first range R1 and flag processing section 84 has set first flag F1, control section 82 permits the delivery of article AR0 between station 50s and carriage 60 (step SP2 to step SP4 illustrated in FIG. 5, number 1 illustrated in FIG. 6). When detection section 81 does not detect that relative position 81p is within first range R1, control section 82 restricts the delivery of article AR0 between station 50s and carriage 60 (step SP2, step SP3, and step SP5 illustrated in FIG. 5, and number 2 and number 4 illustrated in FIG. 6). When detection section 81 detects that relative position 81p is within first range R1 and flag processing section 84 has not set first flag F1, control section 82 restricts the delivery of article AR0 between station 50s and carriage 60 (step SP2, step S3, and step S5 illustrated in FIG. 5, number 3 illustrated in FIG. 6).

Further, control section 82 may determine a possibility of a failure in production facility 1 based on the detection result detected by detection section 81 and the state of first flag F1 processed by flag processing section 84. For example, consider timing 1 ((1) of number 3 illustrated in FIG. 6) when carriage 60 is traveling toward target position S30. At timing 1, the normal state is a state where detection section 81 does not detect that relative position 81p is within first range R1.

Control section 82 determines that there is an abnormality in detector 81s of detection section 81 that detects relative position 81p when, at a timing at which carriage 60 is traveling toward target position S30, detection section 81 detects that relative position 81p is within first range R1 and flag processing section 84 has not set first flag F1. For example, light shielding detection sensor 81b illustrated in FIG. 7 and FIG. 8 corresponds to detector 81s. In this case, for example, the worker checks detector 81s. When there is an abnormality (for example, a failure) in detector 81s, the worker prohibits use of production facility 1 (in the embodiment, carriage 60) including detector 81s, and performs exchange, repair, and the like.

Further, consider timing 2 ((2) of number 3 illustrated in FIG. 6) when position recognition section 83 recognizes that carriage 60 reaches target position S30 and starts the delivery of article AR0. At timing 2, the normal state is a state where flag processing section 84 has set first flag F1. In this case, control section 82 determines that there is an abnormality in guide portion 85 or carriage 60 when, at a timing at which position recognition section 83 recognizes that carriage 60 reaches target position S30 and starts the delivery of article AR0, detection section 81 detects that relative position 81p is within first range R1 and flag processing section 84 has not set first flag F1.

For example, guide member M0 and indicator member S0 illustrated in FIG. 1 are included in guide portion 85. For example, consider the case where flag processing section 84 has set first flag F1 at a timing at which traveling position 60p of carriage 60 recognized by position recognition section 83 reaches target position S30. For example, even if traveling position 60p of carriage 60 reaches target position S30, when the target member indicating target position S30 is detached, there is a possibility that flag processing section 84 has not set first flag F1. In addition, the abnormality in position recognition section 83 provided in carriage 60 (in the embodiment, automated guided vehicle 70 towing carriage 60) is included in the abnormality of carriage 60. In this case, for example, the worker checks guide portion 85 or carriage 60. When there is an abnormality in guide portion 85 or carriage 60, the worker prohibits the use of production facility 1 provided with guide portion 85 or carriage 60, and performs exchange, repair, and the like.

Further, consider timing 3 when carriage 60 returns to a normal state after an abnormality occurs in carriage 60, or timing 4 ((3) of number 3 in FIG. 6) when the control of carriage 60 is resumed after the control of carriage 60 is stopped. At timing 3 or timing 4, when detection section 81 detects that relative position 81p is within first range R1 and flag processing section 84 has not set first flag F1, for example, there is a possibility that carriage 60 may be moved by the worker.

Control section 82 retracts carriage 60 from second range R2 when, at a timing at which carriage 60 returns to a normal state after an abnormality occurs in carriage 60, or at a timing at which the control of carriage 60 is resumed after the control of carriage 60 is stopped, detection section 81 detects that relative position 81p is within first range R1 and flag processing section 84 has not set first flag F1. As a result, control section 82 can avoid interference between carriage 60 and other members, including station 50s, that may occur when carriage 60 revolves.

Further, consider timing 2 ((1) of number 4 illustrated in FIG. 6) when position recognition section 83 recognizes that carriage 60 reaches target position S30 and starts the delivery of article AR0. At timing 2, when detection section 81 has not detected that relative position 81p is within first range R1 and flag processing section 84 has set first flag F1, there is a possibility that the movement of carriage 60 may be insufficient.

Control section 82 moves carriage 60 toward target position S30 again when, at a timing at which position recognition section 83 recognizes that carriage 60 reaches target position S30 and starts the delivery of article AR0, detection section 81 does not detect that relative position 81p is within first range R1 and flag processing section 84 has set first flag F1. Further, control section 82 can stop the movement of carriage 60 when detection section 81 does not detect that relative position 81p is within first range R1 even when carriage 60 is moved toward target position S30 by a predetermined number of times. In this case, for example, the worker checks the state of carriage 60.

At timing 1 when carriage 60 is traveling toward target position S30, there may be cases where detection section 81 does not detect that relative position 81p is within first range R1 and flag processing section 84 has set first flag F1 ((1) of number 4 illustrated in FIG. 6). Specifically, when carriage 60 is traveling in second range R2, the state described above occurs. In the state described above, there is a possibility that station 50s and carriage 60 may be brought closer to each other, and for convenience, the state described above is classified as an abnormal state. Also in this case, the movement of carriage 60 is insufficient, and control section 82 moves carriage 60 toward target position S30. When carriage 60 is traveling outside second range R2, there may be cases where detection section 81 does not detect that relative position 81p is within first range R1 and flag processing section 84 has not set first flag F1 (number 2 illustrated in FIG. 6). In this state, there is no possibility that station 50s and carriage 60 are brought closer to each other, and the detection result detected by detection section 81 and the state of first flag F1 processed by flag processing section 84 do not contradict each other and this state is classified as a normal state.

Next, consider timing 3 when carriage 60 returns to a normal state after an abnormality occurs in carriage 60, or timing 4 ((2) of number 4 in FIG. 6) when the control of carriage 60 is resumed after the control of carriage 60 is stopped. At timing 3 or timing 4, when detection section 81 does not detect that relative position 81p is within first range R1 and flag processing section 84 has set first flag F1, for example, there is a possibility that carriage 60 may be moved by the worker.

Control section 82 moves carriage 60 toward target position S30 after retracting carriage 60 from second range R2 when, at a timing at which carriage 60 returns to a normal state after an abnormality occurs in carriage 60, or at a timing at which the control of carriage 60 is resumed after the control of carriage 60 is stopped, detection section 81 does not detect that relative position 81p is within first range R1 and flag processing section 84 has set first flag F1. As a result, control section 82 can move carriage 60 toward target position S30 while avoiding interference between carriage 60 and other members, including station 50s, that may occur when carriage 60 revolves.

### 1-2-4. Other Embodiments

Flag processing section 84 of the embodiment operates while carriage 60 is automatically operating. Therefore, for example, flag processing section 84 does not change the state of first flag F1 while an abnormality occurs in carriage 60. Similarly, flag processing section 84 does not change the state of first flag F1 while the control of carriage 60 is stopped. Accordingly, during the period described above, control section 82 can acquire the processing result executed by flag processing section 84 while carriage 60 is automatically operating, and can perform the determination and control described above.

In addition, flag processing section 84 of the embodiment sets first flag F1 at a timing at which traveling position 60p of carriage 60 recognized by position recognition section 83 reaches target position S30, or at a timing at which traveling position 60p of carriage 60 enters second range R2. Flag processing section 84 unsets first flag F1 at a timing at which traveling position 60p of carriage 60 recognized by position recognition section 83 is away from target position S30, or at a timing at which traveling position 60p of carriage 60 is retracted outside second range R2. Accordingly, for example, flag processing section 84 of the embodiment does not change the state of first flag F1 at timing 3 at which carriage 60 returns to a normal state after an abnormality occurs in carriage 60, or at timing 4 at which the control of carriage 60 is resumed after the control of carriage 60 is stopped. As a result, during automatic operation, carriage 60 can more reliably deliver article AR0 based on the detection result detected by detection section 81 and the state of first flag F1 processed by flag processing section 84. In addition, control section 82 can determine a failure in production facility 1, or the like. Further, for example, at timing 3 or timing 4, control section 82 can determine whether carriage 60 has been brought closer to station 50s by the worker or whether carriage 60 has been moved away from station 50s by the worker.

However, article conveyance system 80 may include flag processing section 84 capable of unsetting the flag regardless of the timings described above. Specifically, flag processing section 84 of the modified embodiment sets second flag F2 when traveling position 60p of carriage 60, which is automatically operating, recognized by position recognition section 83 reaches target position S30 where carriage 60 performs the delivery of article AR0 to and from station 50s, or enters second range R2 where the adjustment operation to target position S30 is performed, and then flag processing section 84 unsets second flag F2, regardless of whether carriage 60 is in automatic operation, when traveling position 60p of carriage 60 recognized by position recognition section 83 is away from target position S30 or is retracted outside second range R2.

In the modified embodiment, when detection section 81 detects that relative position 81p is within first range R1 and flag processing section 84 has set second flag F2, control section 82 permits the delivery of article AR0 between station 50s and carriage 60. When detection section 81 does not detect that relative position 81p is within first range R1, or detection section 81 detects that relative position 81p is within first range R1 and flag processing section 84 has not set second flag F2, control section 82 restricts the delivery of article AR0 between station 50s and carriage 60.

Second flag F2 is replaced for convenience in order to identify second flag F2 from first flag F1, and is similar to first flag F1. Further, the above description of target position S30, second range R2, the operation of first flag F1, and the like may also be appropriately applied to flag processing section 84 of the modified embodiment. Furthermore, the above description of station 50s, carriage 60, detection section 81, and control section 82 described above can also be appropriately applied to flag processing section 84 of the modified embodiment.

After second flag F2 is set, flag processing section 84 of the modified embodiment unsets second flag F2, regardless of whether carriage 60 is in automatic operation, when traveling position 60p of carriage 60 recognized by position recognition section 83 is away from target position S30 or is retracted outside second range R2. That is, flag processing section 84 of the modified embodiment can unset second flag F2 even at a timing other than the timing at which traveling position 60p of carriage 60 recognized by position recognition section 83 is away from target position S30 by automatic operation of carriage 60 or other than the timing at which traveling position 60p of carriage 60 is retracted outside second range R2 by automatic operation of carriage 60.

For example, consider timing 3 when carriage 60 returns to a normal state after an abnormality occurs in carriage 60, or timing 4 when the control of carriage 60 is resumed after the control of carriage 60 is stopped. At timing 3 or timing 4, as described above, for example, there is a possibility that carriage 60 may be moved by the worker. Flag processing section 84 of the modified embodiment determines whether traveling position 60p of carriage 60 recognized by position recognition section 83 is away from target position S30 at timing 3 or at timing 4. When traveling position 60p of carriage 60 recognized by position recognition section 83 is away from target position S30, flag processing section 84 of the modified embodiment unsets second flag F2 regardless of whether carriage 60 is in automatic operation. When traveling position 60p of carriage 60 recognized by position recognition section 83 is not away from target position S30 (traveling position 60p is target position S30), flag processing section 84 of the modified embodiment maintains a state where second flag F2 is set regardless of whether carriage 60 is in automatic operation. Accordingly, when carriage 60 returns to a normal state, carriage 60 can smoothly resume automatic operation based on traveling position 60p of carriage 60.

Similarly, when traveling position 60p of carriage 60 recognized by position recognition section 83 is retracted outside second range R2, flag processing section 84 of the modified embodiment can unset second flag F2 regardless of whether carriage 60 is in automatic operation. When traveling position 60p of carriage 60 recognized by position recognition section 83 is not retracted outside second range R2 (traveling position 60p is within second range R2), flag processing section 84 of the modified embodiment can maintain a state where second flag F2 is set regardless of whether carriage 60 is in automatic operation. Thus, flag processing section 84 of the modified embodiment can be executed at any timing regardless of whether carriage 60 is in automatic operation. Then, based on traveling position 60p of carriage 60 recognized by position recognition section 83, flag processing section 84 of the modified embodiment can unset second flag F2 regardless of whether carriage 60 is in automatic operation. Accordingly, when carriage 60 returns to a normal state, carriage 60 can smoothly resume automatic operation based on traveling position 60p of carriage 60. Position recognition section 83 can recognize traveling position 60p of carriage 60 according to the method described above.

Board work machine WM0 need only perform a predetermined board work on a board, and is not limited to component mounter 10. Production facility 1 may include various board work machines WM0. For example, production facility 1 may include board work machine WM0 such as a solder printer, a solder inspection machine, a reflow oven, and a visual inspection machine. Similarly, article AR0 need only be used for board work machine WM0, and is not limited to feeder 20. For example, the reel on which a component tape for accommodating the components to be mounted on the board is wound is included in article AR0. Further, a component tray in which the components to be mounted on the board are arranged is included in article AR0.

Further, a holding member (for example, a suction nozzle, a chuck, or the like) for collecting and holding the components is included in article AR0. Further, a mounting head on which the components are mounted on the board using a holding member is included in article AR0. Further, the holding member accommodation device capable of accommodating the holding member is included in article AR0. In the case where board work machine WM0 is a printer that moves solder along a mask to print the solder on a board using a squeegee, the squeegee, the mask, a backup member that supports the board, and a solder container that accommodates the solder are included in article AR0. Further, in the cases where board work machine WM0 is component mounter 10 or a printer that is provided with a liquid material application mechanism applying a liquid material such as an adhesive material or solder to each of multiple printing positions on a board using a print head, a liquid material container accommodating the liquid material used for the print head and a dispense head, and the liquid material application mechanism are included in article AR0. The shape of accommodation case 90 may be modified to suit article AR0 to be accommodated, and in this case, loading platform 62 of carriage 60 may be modified to correspond to accommodation case 90.

In the embodiment, carriage 60 performs the delivery of accommodation case 90 accommodating feeder 20 to and from station 50s provided in station group 50 on the board convey-in side of production facility 1. However, station 50s that delivers article AR0 is not limited to the embodiment described above. For example, carriage 60 can perform the delivery of accommodation case 90 accommodating feeder 20 to and from board work machine WM0. For example, carriage 60 can perform the delivery of accommodation case 90 accommodating feeder 20 to and from the first position of component mounter 10. The embodiment described above can be applied as needed to board work machine WM0 provided in production facility 1.

Further, carriage 60 is not limited to the form of being towed by automated guided vehicle 70. For example, as illustrated in FIG. 10, carriage 60 may be automated guided vehicle 70 in which carriage main body section 61 and loading platform 62 described above are detachably provided. Further, carriage 60 may be automated guided vehicle 70 in which carriage main body section 61 and loading platform 62 described above are integrally formed. Production facility 1 may further include a storage that stores article AR0. Production facility 1 can be provided with a setup change area in which setup change of board work machine WM0 is performed. Carriage 60 can perform the delivery of article AR0 to and from station 50s provided in the storage, and can also perform the delivery of article AR0 to and from station 50s provided in the setup change area.

The recognition of traveling position 60p of carriage 60 by position recognition section 83 is not limited to recognizing guide portion 85 formed by the magnetic tape. For example, conveyance management device CC0 may recognize traveling position 60p of carriage 60 based on an image or a moving image captured by a camera capable of capturing the travel route of carriage 60, and issue a traveling instruction to carriage 60. Further, conveyance management device CC0 may recognize traveling position 60p of carriage 60 based on the detection result of the sensor installed at a predetermined position in the travel route of carriage 60, and issue a traveling instruction to carriage 60. As illustrated in FIG. 9, when traveling position 60p of carriage 60 reaches target position S30, relative position 81p between station 50s and carriage 60 may be spaced apart from traveling position 60p and target position S30 by a specified distance. When traveling position 60p of carriage 60 reaches target position S30, relative position 81p between station 50s and carriage 60 may be aligned with traveling position 60p and target position S30.

### 2. Article Conveyance Method

The above description of article conveyance system 80 can be similarly applied to the article conveyance method. Specifically, the article conveyance method includes a detection step and a control step. The detection step detects relative position 81p between station 50s configured to deliver article AR0, which is used for board work machine WM0 performing a predetermined board work on a board, and carriage 60 configured to automatically convey article AR0 into or out of station 50s and travel. In the control step, when relative position 81p detected in the detection step is within first range R1 where the delivery of article AR0 is deliverable between station 50s and carriage 60, the delivery of article AR0 between station 50s and carriage 60 is permitted, and when relative position 81p detected in the detection step is not within first range R1, the delivery of article AR0 between station 50s and carriage 60 is restricted.

That is, the control performed by detection section 81 corresponds to the detection step. The control performed by control section 82 corresponds to the control step. The article conveyance method may include a position recognition step. The article conveyance method may include a flag processing step. The control performed by position recognition section 83 corresponds to the position recognition step. The control performed by flag processing section 84 corresponds to the flag processing step. Production facility 1 to which the article conveyance method is applied may include guide portion 85.

### 3. Example of Effects of Embodiment

With article conveyance system 80, when detection section 81 detects that relative position 81p between station 50s and carriage 60 is within first range R1, control section 82 permits delivery of article AR0 between station 50s and carriage 60. In addition, when detection section 81 does not detect that relative position 81p between station 50s and carriage 60 is within first range R1, control section 82 restricts the delivery of article AR0 between station 50s and carriage 60. Therefore, article conveyance system 80 is capable of reliably performing the delivery of article AR0 between station 50s and carriage 60. The above description of article conveyance system 80 can be similarly applied to the article conveyance method.

### REFERENCE SIGNS LIST

1: Production facility, 50s: Station, 50t: Station side contact portion,
60: Carriage, 60p: Traveling position, 60t: Carriage side contact portion,
80: Article conveyance system, 81: Detection section, 81p: Relative position,
81s: Detector, 82: Control section, 83: Position recognition section, 84: Flag processing section,
85: Guide portion, AR0: Article, R1: First range, R2: Second range,
F1: First flag, F2: Second flag, S30: Target position,
WM0: Board work machine.

1. An article conveyance system comprising:
a station configured to deliver an article, which is used for a board work machine performing a predetermined board work on a board;
a carriage configured to automatically convey the article into or out of the station and travel;
a detection section provided on at least one of the station and the carriage, and configured to detect a relative position between the station and the carriage; and
a control section configured to permit delivery of the article between the station and the carriage when the detection section detects that the relative position is within a first range where the article is deliverable between the station and the carriage, and restrict the delivery of the article between the station and the carriage when the detection section does not detect that the relative position is within the first range.

2. The article conveyance system according to claim 1,
wherein the detection section detects that the relative position is within the first range when a station side contact portion provided in the station and a carriage side contact portion provided on the carriage are in contact with each other, and does not detect that the relative position is within the first range when the station side contact portion and the carriage side contact portion are not in contact with each other.

3. The article conveyance system according to claim 1, further comprising:
a position recognition section configured to recognize a traveling position where the carriage is traveling; and
a flag processing section configured to set a first flag at a timing at which the traveling position of the carriage recognized by the position recognition section reaches a target position where the carriage performs the delivery of the article to and from the station or a timing at which the traveling position of the carriage recognized by the position recognition section enters a second range where an adjustment operation to the target position is performed; and unset the first flag at a timing at which the traveling position of the carriage recognized by the position recognition section is away from the target position, or at a timing at which the traveling position of the carriage recognized by the position recognition section is retracted outside the second range, which are executed while the carriage is automatically operating, and
wherein the control section permits the delivery of the article between the station and the carriage when the detection section detects that the relative position is within the first range and the flag processing section has set the first flag, and restricts the delivery of the article between the station and the carriage when the detection section does not detect that the relative position is within the first range, or when the detection section detects that the relative position is within the first range and the flag processing section has not set the first flag.

4. The article conveyance system according to claim 3,
wherein the adjustment operation is an operation of bringing the carriage closer to the target position while adjusting a position and an angle of the carriage with respect to the station in a movement to the target position where the carriage performs the delivery of the article to and from the station.

3. The article conveyance system according to claim 3,
wherein the control section determines a possibility of a failure in a production facility based on a detection result detected by the detection section and a state of the first flag processed by the flag processing section.

6. The article conveyance system according to claim 5,
wherein the control section determines that there is an abnormality in a detector of the detection section that detects the relative position when, at a timing at which the carriage is traveling toward the target position, the detection section detects that the relative position is within the first range and the flag processing section has not set the first flag.

7. The article conveyance system according to claim 5, further comprising:
a guide portion that is a member provided along a travel route of the carriage and configured to guide travel of the carriage,
wherein the carriage travels while recognizing the guide portion, and
the control section determines that there is an abnormality in the guide portion or the carriage when, at a timing at which the position recognition section recognizes that the carriage reaches the target position and starts delivery of the article, the detection section detects that the relative position is within the first range and the flag processing section has not set the first flag.

8. The article conveyance system according to claim 3,
wherein the control section retracts the carriage from the second range when, at a timing at which the carriage returns to a normal state after an abnormality occurs in the carriage, or at a timing at which control of the carriage is resumed after the control of the carriage is stopped, the detection section detects that the relative position is within the first range and the flag processing section has not set the first flag.

9. The article conveyance system according to claim 3,
wherein the control section moves the carriage toward the target position again when, at a timing at which the position recognition section recognizes that the carriage reaches the target position and starts the delivery of the article, the detection section does not detect that the relative position is within the first range and the flag processing section has set the first flag.

10. The article conveyance system according to claim 9,
wherein the control section stops the movement of the carriage when the detection section does not detect that the relative position is within the first range even when the carriage is moved toward the target position by a predetermined number of times.

11. The article conveyance system according to claim 3,
wherein the control section moves the carriage toward the target position after retracting the carriage from the second range when, at a timing at which the carriage returns to a normal state after an abnormality occurs in the carriage, or at a timing at which control of the carriage is resumed after the control of the carriage is stopped, the detection section does not detect that the relative position is within the first range and the flag processing section has set the first flag.

12. The article conveyance system according to claim 1, further comprising:
a position recognition section configured to recognize a traveling position where the carriage is traveling; and
a flag processing section configured to set a second flag when the traveling position of the carriage, which is automatically operating, recognized by the position recognition section reaches a target position where the carriage performs the delivery of the article to and from the station, or enter a second range where an adjustment operation to the target position is performed, and then unset the second flag, regardless of whether the carriage is in automatic operation, when the traveling position of the carriage recognized by the position recognition section is away from the target position or is retracted outside the second range, and
the control section permits the delivery of the article between the station and the carriage when the detection section detects that the relative position is within the first range and the flag processing section has set the second flag, and restricts the delivery of the article between the station and the carriage when the detection section does not detect that the relative position is within the first range, or when the detection section detects that the relative position is within the first range and the flag processing section has not set the second flag.

13. An article conveyance method comprising:
a detection step of detecting a relative position between a station configured to deliver an article, which is used for a board work machine performing a predetermined board work on a board, and a carriage configured to automatically convey the article into or out of the station and travel; and
a control step of permitting delivery of the article between the station and the carriage when the relative position detected in the detection step is within a first range where the article is deliverable between the station and the carriage, and restricting the delivery of the article between the station and the carriage when the relative position detected in the detection step is not within the first range.
